(19) United States
(12) Patent Application Publication
(10) Pub. No.: US 2019/0067041 A1
(43) Pub. Date: Feb. 28, 2019

(54) SUBSTRATE PROCESSING APPARATUS, SUBSTRATE PROCESSING METHOD, AND STORAGE MEDIUM

(71) Applicant: Tokyo Electron Limited, Tokyo (JP)

(72) Inventor: Akira Fujita, Kumamoto (JP)

(21) Appl. No.: 16/106,729

(22) Filed: Aug. 21, 2018

(30) Foreign Application Priority Data
Aug. 23, 2017 (JP) 2017-160538

(51) Int. Cl. H01L 21/67; H01L 21/306; H01L 21/683

(52) U.S. Cl. CPC H01L 21/6708; H01L 21/6838; H01L 21/30604

(57) ABSTRACT

A substrate processing apparatus includes: a holding unit; a rotation driving unit; a processing liquid supply unit; a processing liquid nozzle driving unit that moves the processing liquid nozzle among a first processing position, a second processing position which is positioned closer to a center side of the substrate than the first processing position, and a retreat position that is retreated from the substrate; and a controller. The controller controls the units so as to perform a first moving of moving the processing liquid nozzle from the retreat position to the first processing position while rotating the substrate at a first rotational speed, and a second moving of moving the processing liquid nozzle from the first processing position to the second processing position while rotating the substrate at a second rotational speed that is higher than the first rotational speed.

### CROSS-REFERENCE TO RELATED APPLICATIONS

This application is based on and claims priority from Japanese Patent Application No. 2017-160538, filed on Aug. 23, 2017 with the Japan Patent Office, the disclosure of which is incorporated herein in its entirety by reference.

### TECHNICAL FIELD

The present disclosure relates to a substrate processing apparatus, a substrate processing method, and a storage medium.

### BACKGROUND

In a manufacturing process of a semiconductor device in which a stacked structure (device) of an integrated circuit is formed on a top surface of a semiconductor wafer (hereinafter, referred to as a “wafer”) serving as a substrate, a portion of a natural oxide film formed on a top surface of a wafer, which is formed in a peripheral portion of the wafer, is removed with a chemical liquid such as hydrofluoric acid (see, e.g., Japanese Patent Laid-Open Publication No. 2012-164858). Removal of such a natural oxide film may be referred to as “bevel cleaning” or “edge cleaning.”

### SUMMARY

According to an embodiment of the present disclosure, there is provided a substrate processing apparatus including: a holding unit configured to hold a substrate in a horizontal direction; a rotation driving unit configured to rotate the holding unit, a processing liquid supply unit including a processing liquid nozzle configured to eject a processing liquid; a processing liquid nozzle driving unit configured to move the processing liquid nozzle among a first processing position where the processing liquid is supplied to the substrate, a second processing position that is positioned closer to a center side of the substrate than the first processing position where the processing liquid is supplied to the substrate, and a retreat position that is retreated from the substrate; and a controller configured to control an overall operation of the substrate processing apparatus. The controller controls the rotation driving unit, the processing liquid supply unit, and the processing liquid nozzle driving unit so as to perform a first moving of moving the processing liquid nozzle from the retreat position to the first processing position while rotating the substrate at a first rotational speed and ejecting the processing liquid from the processing liquid nozzle, and, after performing the first moving, a second moving of moving the processing liquid nozzle from the first processing position to the second processing position while rotating the substrate at a second rotational speed that is higher than the first rotational speed and ejecting the processing liquid from the processing liquid nozzle.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a schematic configuration of a substrate processing system according to an embodiment of the present disclosure.

FIG. 2 is a schematic vertical sectional view of the substrate processing apparatus according to the embodiment of the present disclosure.

FIG. 3 is a schematic plan view illustrating each nozzle of FIG. 2.

FIG. 4 is a view for explaining a discharge direction of hydrofluoric acid from a hydrofluoric acid nozzle of FIG. 3, and a schematic vertical sectional view taken along a line A-A in FIG. 3.

FIG. 5 is a view for explaining a discharge direction of hydrofluoric acid from a hydrofluoric acid nozzle of FIG. 3, and a schematic vertical sectional view taken along a line B-B in FIG. 3.

FIG. 6 is a schematic plan view for explaining a discharge direction of hydrofluoric acid from a hydrofluoric acid nozzle of FIG. 3.

FIG. 7 is a view for explaining a rotation start step in a substrate processing method according to an embodiment of the present disclosure.

FIG. 8 is a view for explaining an ejection start step of hydrofluoric acid following the rotation start step illustrated in FIG. 7.

FIG. 9 is a view for explaining a first moving step in which the hydrofluoric acid nozzle is moved from a retreat position to a first processing position following the ejection start step illustrated in FIG. 8.

FIG. 10 is a view for explaining a rotational speed increasing step of a wafer following the first moving step illustrated in FIG. 9.

FIG. 11 is a view for explaining a second moving step in which the hydrofluoric acid nozzle is moved from the first processing position to a second processing position following the rotational speed increasing step illustrated in FIG. 10.

FIG. 12 is a view for explaining a natural oxide film removal step following the second moving step illustrated in FIG. 11.

FIG. 13 is a view for explaining a third moving step in which the hydrofluoric acid nozzle is moved from the second step position to the first processing position following the natural oxide film removal step illustrated in FIG. 12.

FIG. 14 is a view for explaining a rotational speed decreasing step of a wafer following the third moving step illustrated in FIG. 13.

FIG. 15 is a view for explaining a fourth moving step in which the hydrofluoric acid nozzle is moved from the first processing position to the retreat position following the rotational speed decreasing step illustrated in FIG. 14.

FIG. 16 is a view for explaining an ejection end step of hydrofluoric acid following the fourth moving step illustrated in FIG. 15.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In order to remove a natural oxide film by etching in a limited region, i.e., a peripheral portion of a wafer, it is aimed to reduce an ejection amount of a chemical liquid to the wafer and improve precision of an etching width in the natural oxide film. When the ejection amount of the chemical liquid is reduced, the ejection amount becomes unstable immediately after the ejection of the chemical liquid is started. Therefore, in a case where a natural oxide film in a peripheral portion of a wafer is removed, before supplying the chemical liquid from a nozzle to the peripheral portion of the wafer, the chemical liquid is ejected from the nozzle for a predetermined time at a retreat position retreated from the wafer. Thereafter, by moving the nozzle to the peripheral portion of the wafer while ejecting the chemical liquid, the ejection amount of the chemical liquid from the nozzle becomes stable when the nozzle supplies the chemical liquid to the peripheral portion of the wafer.

However, the nozzle passes over a bevel portion of the wafer while ejecting the chemical liquid. Thus, the ejected chemical liquid collides with the bevel portion and scatters to the surroundings. When the scattered chemical liquid adheres to a surface of the natural oxide film remaining after etching, it may become a particle source. Particularly, in recent years, particle inspection targets have become smaller, or an inspection range for particles is expanded in the radial direction, so that countermeasures against particles are urgently required.

The present disclosure has been made in view of these points, and the present disclosure is to provide a substrate processing apparatus capable of suppressing generation of particles on an upper surface of a substrate, a substrate processing method, and a storage medium.

According to an embodiment of the present disclosure, there is provided a substrate processing apparatus including: a holding unit configured to hold a substrate in a horizontal direction; a rotation driving unit configured to rotate the holding unit; a processing liquid supply unit including a processing liquid nozzle configured to eject a processing liquid; a processing liquid nozzle driving unit configured to move the processing liquid nozzle among a first processing position where the processing liquid is supplied to the substrate, a second processing position that is positioned closer to a center side of the substrate than the first processing position where the processing liquid is supplied to the substrate, and a retreat position that is retreated from the substrate; and a controller configured to control an overall operation of the substrate processing apparatus. The controller controls the rotation driving unit, the processing liquid supply unit, and the processing liquid nozzle driving unit so as to perform a first moving of moving the processing liquid nozzle from the retreat position to the first processing position while rotating the substrate at a first rotational speed and ejecting the processing liquid from the processing liquid nozzle, and, after performing the first moving, a second moving of moving the processing liquid nozzle from the first processing position to the second processing position while rotating the substrate at a second rotational speed that is higher than the first rotational speed and ejecting the processing liquid from the processing liquid nozzle.

In the above-described substrate processing apparatus, the controller controls the rotation driving unit and the processing liquid nozzle driving unit so as to perform a rotational speed increasing of increasing a rotational speed of the substrate from the first rotational speed to the second rotational speed while maintaining the processing liquid nozzle at the first processing position between the first moving and the second moving.

The above-described substrate processing apparatus further includes: a ring-shaped cover member that defines an inner space formed above the substrate that is held by the holding unit and covers a peripheral portion of the substrate via a peripheral space communicating with the inner space; and an exhaust unit that discharge a gas in the inner space of the cover member through the peripheral space. The exhaust unit includes an exhaust amount adjusting unit that adjust an exhaust amount of the gas discharged from the inner space, and the controller controls the exhaust unit so as to discharge the gas in the inner space at a first exhaust amount in the performing of the first moving and discharge the gas in the inner space at a second exhaust amount which is smaller than the first exhaust amount in the performing of the second moving.

In the above-described substrate processing apparatus, the controller controls the exhaust unit so as to decrease the exhaust amount of the gas in the inner space from the first exhaust amount to the second exhaust amount in the performing of the rotational speed increasing.

The above-described substrate processing apparatus further includes: a ring-shaped cover member that defines an inner space formed above the substrate held by the holding unit and covers a peripheral portion of the substrate via a peripheral space communicating with the inner space; and an exhaust unit that discharge a gas in the inner space of the cover member through the peripheral space. The exhaust unit includes an exhaust amount adjusting unit that adjust an exhaust amount of the gas discharged from the inner space, and the controller controls the exhaust unit so as to discharge the gas in the inner space at a first exhaust amount in the first moving and discharge the gas in the inner space at a second exhaust amount that is smaller than the first exhaust amount in the second moving.

In the above-described substrate processing apparatus, the processing liquid nozzle is configured to eject a plurality of types of processing liquids different from each other, and the processing liquid ejected from the processing liquid nozzle in the first moving and the processing liquid ejected from the processing liquid nozzle in the second moving are different from each other.

According to another embodiment of the present disclosure, there is provided a substrate processing method including: holding a substrate on a holding unit in a horizontal direction; performing a first moving of moving a processing liquid nozzle from a retreat position that is retreated from the substrate to a first processing position where a processing liquid is supplied to the substrate while rotating the substrate at a first rotational speed and ejecting the processing liquid from the processing liquid nozzle; and after performing the first moving, performing a second moving of moving the processing liquid nozzle from the first processing position to a second processing position that is positioned closer to a center side of the substrate than the first processing position where the processing liquid is supplied to the substrate while rotating the substrate at a second rotational speed that is higher than the first rotational speed and ejecting the processing liquid from the processing liquid nozzle.

The above-described substrate processing method further includes performing a rotational speed increasing of increasing the rotational speed of the substrate from the first rotational speed to the second rotational speed while maintaining the processing liquid nozzle at the first processing position between the first moving and the second moving.

In the above-described substrate processing method, a ring-shaped cover member is disposed above the substrate, the cover member defines an inner space formed above the substrate, a peripheral portion of the substrate is covered with the cover member via a peripheral space communicating with the inner space, and a gas in the inner space is discharged at a first exhaust amount in the performing of the first moving and the gas in the inner space is discharged through the peripheral space at a second exhaust amount that is smaller than the first exhaust amount in the performing of the second moving.

In the above-described substrate processing method, an exhaust amount of the gas in the peripheral space is decreased from the first exhaust amount to the second exhaust amount in the rotational speed increasing.

In the above-described substrate processing method, a ring-shaped cover member is disposed above the substrate, the cover member defines an inner space formed above the substrate, a peripheral portion of the substrate is covered with the cover member via a peripheral space communicating with the inner space, and a gas in the inner space is discharged at a first exhaust amount in the performing of the first moving and the gas in the inner space is discharged through the peripheral space at a second exhaust amount that is smaller than the first exhaust amount in the performing of the second moving.

In the above-described substrate processing method, the processing liquid nozzle is configured to eject a plurality of types of processing liquids different from each other, and the processing liquid ejected from the processing liquid nozzle in the performing of the first moving and the processing liquid ejected from the processing liquid nozzle in the performing of the second moving are different from each other.

According to still another embodiment of the present disclosure, there is provided a non-transitory computer-readable storage medium that stores a program that causes a computer to control the substrate processing apparatus and to execute the above-described substrate processing method.

According to the present disclosure, it is possible to suppress generation of particles on an upper surface of a substrate.

Hereinafter, an embodiment of a substrate processing apparatus, a substrate processing method, and a storage medium according to the present disclosure will be described with reference to the drawings. The configuration illustrated in the drawings attached to the present specification may include portions in which, for example, sizes and scales are changed from the actual ones for convenience of illustration and ease of understanding.

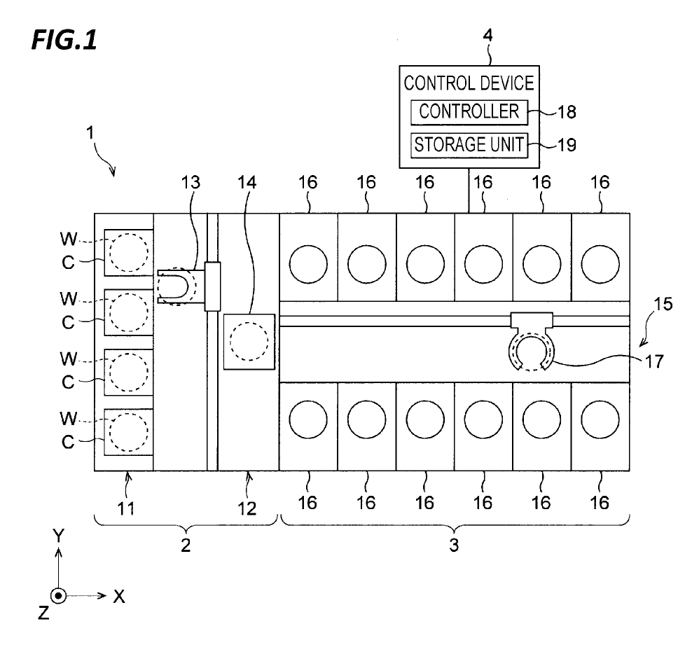

FIG. 1 is a view illustrating a schematic configuration of a substrate processing system according to an embodiment of the present disclosure. Hereinafter, in order to clarify positional relationships, the X-axis, the Y-axis, and the Z-axis are defined as being orthogonal to each other. The positive Z-axis direction is regarded as a vertically upward direction.

As illustrated in FIG. 1, a substrate processing system 1 includes a carry-in/out station 2 and a processing station 3. The carry-in/out station 2 and the processing station 3 are provided adjacent to each other.

The carry-in/out station 2 is provided with a carrier placing section 11 and a transfer section 12. In the carrier placing section 11, a plurality of carriers C are placed to horizontally accommodate a plurality of substrates, i.e., semiconductor wafers (hereinafter, “wafers W”) in the present exemplary embodiment.

The transfer section 12 is provided adjacent to the carrier placing section 11, and provided with a substrate transfer device 13 and a delivery unit 14 therein. The substrate transfer device 13 is provided with a wafer holding mechanism configured to hold the wafer W. Further, the substrate transfer device 13 is movable horizontally and vertically and pivotable around a vertical axis, and transfers the wafers W between the carriers C and the delivery unit 14 by using the wafer holding mechanism.

The processing station 3 is provided adjacent to the transfer section 12. The processing station 3 is provided with a transfer section 15 and a plurality of processing units 16. The plurality of processing units 16 are arranged on both sides of the transfer section 15.

The transfer section 15 is provided with a substrate transfer device 17 therein. The substrate transfer device 17 is provided with a wafer holding mechanism configured to hold the wafer W. Further, the substrate transfer device 17 is movable horizontally and vertically and pivotable around a vertical axis. The substrate transfer device 17 transfers the wafers W between the delivery unit 14 and the processing units 16 by using the wafer holding mechanism.

The processing units 16 perform a predetermined substrate processing on the wafers W transferred by the substrate transfer device 17.

Further, the substrate processing system 1 is provided with a control device 4. The control device 4 is, for example, a computer, and includes a controller 18 and a storage unit 19. The storage unit 19 stores a program that controls various processings performed in the substrate processing system 1. The controller 18 controls the operations of the substrate processing system 1 by reading and executing the program stored in the storage unit 19.

Further, the program may be recorded in a computer-readable recording medium, and installed from the recording medium to the storage unit 19 of the control device 4. The computer-readable recording medium may be, for example, a hard disc (HD), a flexible disc (FD), a compact disc (CD), a magnet optical disc (MO), or a memory card.

In the substrate processing system 1 configured as described above, the substrate transfer device 13 of the carry-in/out station 2 first takes out a wafer W from a carrier C placed in the carrier placing section 11, and then, places the taken wafer W on the delivery unit 14. The wafer W placed on the delivery unit 14 is taken out from the delivery unit 14 by the substrate transfer device 17 of the processing station 3, and carried into a processing unit 16.

The wafer W carried into the processing unit 16 is processed by the processing unit 16, and then, carried out from the processing unit 16 and placed on the delivery unit 14 by the substrate transfer device 17. Then, the processed wafer W, which is placed on the delivery unit 14, returns to the carrier C of the carrier placing section 11 by the substrate transfer device 13.

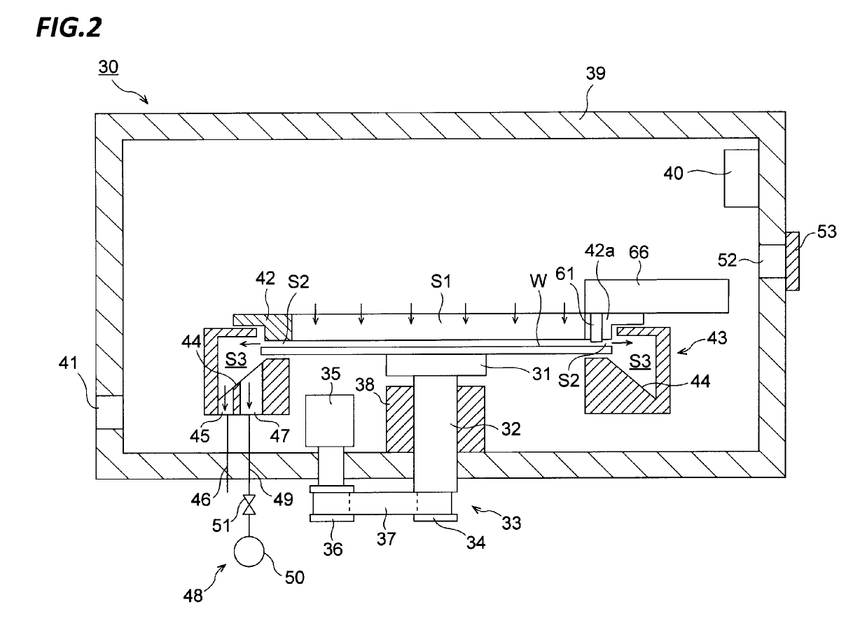

The processing unit 16 illustrated in FIG. 1 includes a processing apparatus 30 illustrated in FIG. 2. Here, the processing apparatus 30 according to the present disclosure is an apparatus for removing a natural oxide film formed in a peripheral portion of the wafer W by etching, and descriptions will be made on an apparatus for removing a natural oxide film by etching using hydrofluoric acid as an example of a processing liquid. Here, the peripheral portion of the wafer W is a ring-shaped region where devices are not formed on the upper surface of the wafer W. The peripheral portion of the wafer W includes a bevel portion Wb (a portion formed in a curved shape on an outer edge side of the wafer W, see, e.g., FIG. 7), and is a region where spans a predetermined distance (e.g., 3 mm) radially inward from an outer edge We of the wafer W.

As illustrated in FIG. 2, the substrate processing apparatus 30 includes a holding unit 31 that horizontally holds a substrate such as a silicon semiconductor wafer (hereinafter, also referred to as a “wafer W”), a rotation shaft 32 that is extended downward from the holding unit 31, and a rotation driving unit 33 that rotates the holding unit 31 via the rotation shaft 32. The holding unit 31 is configured to hold the wafer W placed on the holding unit 31, for example, by vacuum suction.

As illustrated in FIG. 2, the rotation shaft 32 extends in a vertical direction. The rotation driving unit 33 includes a pulley 34 provided at a lower end of the rotation driving unit 32, a motor 35, a pulley 36 provided at a rotation shaft of the motor 36, and a driving belt 37 wound around the pulley 34 and the pulley 36. With such a configuration, rotational driving force of the motor 35 is transmitted to the rotation shaft 32 via the driving belt 37. The rotation shaft 32 is rotatably held in a chamber 39 (to be described later) via bearings 38.

The above-described holding unit 31 and rotation shaft 32 are accommodated in the chamber 39. A clean air introduction unit 40 is provided in the vicinity of a ceiling of the chamber 39 to take in clean air from the outside. Further, an exhaust port 41 is provided in the vicinity of a bottom surface of the chamber 39 to discharge the clean air in the chamber 39. Therefore, a downflow of the clean air flowing from the top to the bottom is formed in the chamber.

A top ring 42 (a cover member) formed in a ring-shaped is provided above the wafer W held by the holding unit 31. The top ring 42 defines an inner space S1 formed above the wafer W held by the holding unit 31. Further, the top ring 42 is provided so as to cover the peripheral portion of the upper surface of the wafer W held by the holding unit 31, and faces the upper surface of the wafer W at a distance. A peripheral space S2 communicating with the inner space S1 is interposed between the top ring 42 and the peripheral portion of the wafer W. The peripheral space S2 is a space through which the clean air supplied from the clean air introduction unit 40 to the inner space S1 of the top ring 42 passes when the clean air flows to a cup body (to be described later). By the peripheral space S2, a flow passage of the clean air is narrowed, the flow of the clean air is rectified so as to direct toward the outer peripheral side of the wafer, and a flow speed of the clean air is increased. Therefore, the processing liquid (e.g., hydrofluoric acid or deionized water (DIW) to be described later) scattered from the peripheral portion of the wafer W is discharged to the outer peripheral side, thereby suppressing the processing liquid from flowing back to the wafer W and adhering thereto.

A cup body 43 is provided around the wafer W held by the holding unit 31. The cup body 43 is a ring-shaped member provided so as to surround the outer periphery of the holding unit 31. The cup body 43 has a role of receiving and collecting the processing liquid scattered from the wafer W, and discharging the processing liquid to the outside.

The cup body 43 includes a ring-shaped recessed portion 44 formed along the circumferential direction of the cup body 43. A cup space S3 of the cup body 43 is defined by the recessed portion 44. A drain port 45 is formed at a bottom of the recessed portion 44, and a drain passage 46 is connected to the drain port 45. An exhaust port 47 is formed at the inner side of the drain passage in the recessed portion 44, and an exhaust unit 48 is connected to the exhaust port 47. The exhaust unit 48 is configured to discharge the clean air (gas) in the inner space S1 of the top ring 42 described above via the peripheral space S2. More specifically, the exhaust unit 48 includes an exhaust passage 49 connected to the exhaust port 47, an exhaust driving unit 50 (e.g., an ejector or a vacuum pump) provided at the exhaust passage 49, and a flow rate adjusting valve 51 (exhaust amount adjusting unit) provided on the exhaust passage 49 at an upstream side (at the exhaust port 47 side) of the exhaust driving unit 50. The flow rate adjusting valve 51 (e.g., a damper valve) is configured to adjust a flow rate of the clean air discharged from the inner space S1 (corresponding to an exhaust amount of the clean air that passes through the exhaust passage 49) by adjusting the degree of opening thereof. While processing the wafer W, the exhaust driving unit 50 is driven so that the clean air in the cup space S3 is attracted and exhausted. Meanwhile, a part of the clean air from the clean air introduction unit 40 is supplied to the inner space S1 of the top ring 42 by the downflow, and the clean air in the inner space S1 passes through the peripheral space S2 between the top ring 42 and the wafer W and is drawn into the cup space S3.

Although not illustrated in FIG. 2, a plurality of exhaust ports 47 are formed in the circumferential direction of the recessed portion 44 of the cup body 43. Therefore, the clean air in the inner space Si is uniformly discharged to the circumferential direction of the wafer W.

A side opening 52 is formed on a side portion of the chamber 38 to carry the wafer W into the chamber 39 or to carry the wafer W out from the chamber 39. A shutter 53 that is able to be opened and closed is provided at the side opening 52.

The top ring 42 may be raised and lowered by an elevating mechanism (not illustrated). Further, the cup body 43 may be raised and lowered by another elevating mechanism (not illustrated). When performing the delivery of the wafer W between an arm of the substrate transfer device 17 and the holding unit 31, the top ring 42 is raised from the position illustrated in FIG. 2, and the cup body 43 is lowered from the position illustrated in FIG. 2.

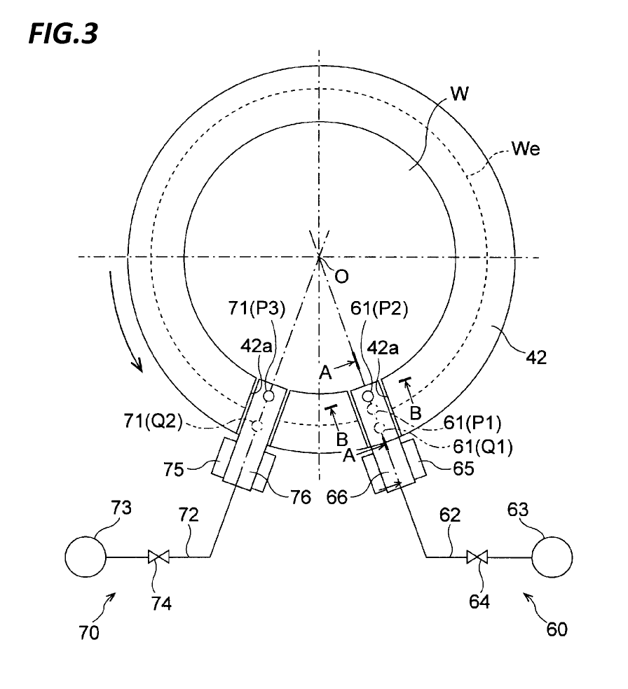

As illustrated in FIG. 2, a processing liquid nozzle 61 configured to supply hydrofluoric acid (processing liquid) to the peripheral portion of the wafer W held by the holding unit 31 is provided in the chamber 39. As illustrated in FIG. 3, the processing liquid nozzle 61 is configured to supply hydrofluoric acid (HF, processing liquid) to the peripheral portion of the wafer W held by the holding unit 31. More specifically, as illustrated in FIG. 3, a processing liquid supply source 63 is connected to the processing liquid nozzle 61 via a processing liquid supply pipe 62. Hydrofluoric acid is supplied from the processing liquid supply source 63 to the processing liquid nozzle 61 via the processing liquid supply pipe 62. A processing liquid valve 64 that controls presence or absence of supply of hydrofluoric acid or a supply amount of hydrofluoric acid to the processing liquid nozzle 61 is provided on the processing liquid supply pipe 62. A processing liquid supply unit 60 that supplies hydrofluoric acid to the peripheral portion of the wafer W held by the holding unit 31 is constituted by these processing liquid nozzle 61, the processing liquid supply pipe 62, the processing liquid supply source 63, and the processing liquid valve 64. The processing liquid nozzle 61 is disposed inside a recessed portion 42a formed at the top ring 42.

As illustrated in FIG. 3, the processing liquid nozzle 61 is connected to a processing liquid nozzle driving unit 65 via a processing liquid nozzle arm 66. The processing liquid nozzle driving unit 65 moves the processing liquid nozzle 61 between a first processing position P1 and a second processing position where hydrofluoric acid is supplied to the peripheral portion of the wafer W and a retreat position Q1 that is retreated from the wafer W. The processing liquid nozzle 61 moves in a radial direction of the wafer W among the first processing position P1, the second processing position P2, and the retreat position Q1. The second processing position P2 is positioned closer to the center O side of the wafer W than the first processing position P1, and is set at such a position where hydrofluoric acid may be supplied such that a desired width region (hereinafter, referred to as a “etching width”) is removed from the outer edge We of the wafer W in the natural oxide film formed on the upper surface of the wafer W. The retreat position Q1 is set at such a position where the hydrofluoric acid ejected from the processing liquid nozzle 61 does not reach the upper surface of the wafer W. The first processing position P1 is set between the second processing position P2 and the retreat position Q1 where hydrofluoric acid may be supplied to the peripheral portion of the wafer W.

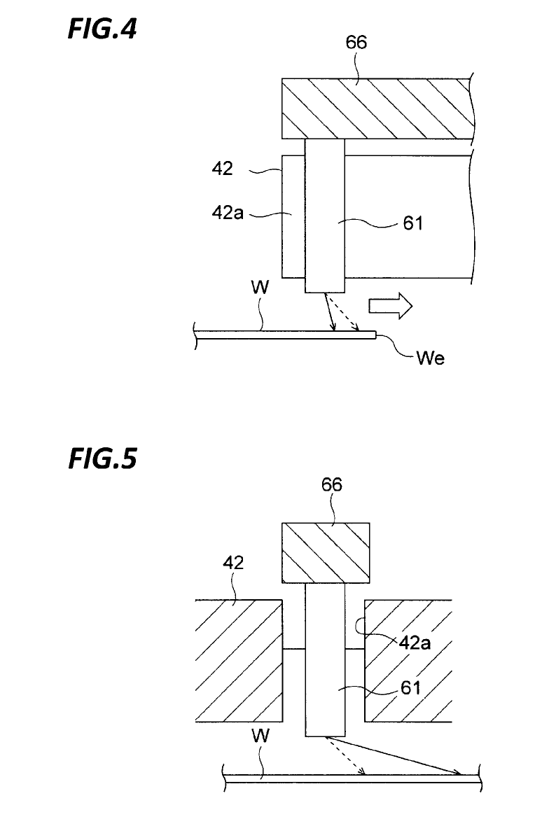

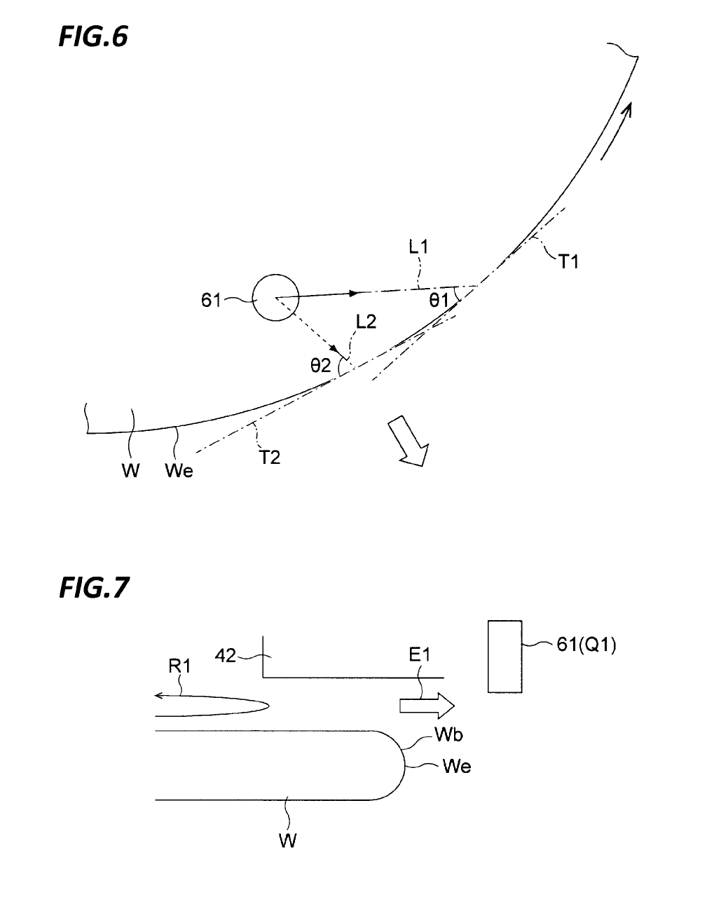

As illustrated in FIGS. 4 to 6, the processing liquid nozzle 61 is configured to eject hydrofluoric acid at a predetermined angle with respect to the upper surface of the wafer W. More specifically, as indicated by a solid line arrow in FIG. 4, when viewed in a direction orthogonal to the radial direction of the wafer W, the ejecting direction of hydrofluoric acid is inclined outward in the radial direction of the wafer W from the vertically downward side. Further, as indicated by a solid line arrow in FIG. 5, when viewed in the radial direction of the wafer W, the ejecting direction of hydrofluoric acid is inclined toward a downstream side of the rotation direction of the wafer W from the vertically downward side. As a result, when viewed from above the wafer W, as indicated by a solid line arrow in FIG. 6, the ejecting direction of hydrofluoric acid from the processing liquid nozzle 61 is represented by the angle 01 illustrated in FIG. 6. In this case, the accuracy of the etching width of the natural oxide film may be improved. Here, the angle θ1 is defined as an angle formed by an extension line L1 of the solid line arrow indicating the ejecting direction of hydrofluoric acid from the processing liquid nozzle 61 and a tangent line T1 of the wafer W at an intersection of the extension line L1 and the outer edge We of the wafer W.

A DIW nozzle 71 is also provided in the same manner as the processing liquid nozzle 61. As illustrated in FIG. 3, the DIW nozzle 71 is disposed in a different position in the circumferential direction of the wafer W from the processing liquid nozzle 61.

As illustrated in FIG. 3, the DIW nozzle 71 is configured to supply deionized water (DIW) to the peripheral portion of the wafer W held by the holding unit 31. More specifically, a DIW supply source 73 is connected to the DIW nozzle 71 via a DIW supply pipe 72. DIW is supplied from the DIW supply source 73 to the DIW nozzle 71 via the DIW supply pipe 72. A DIW valve 74 that controls presence or absence of supply of DIW or a supply amount of DIW to the DIW nozzle 71 is provided on the DIW supply pipe 72. A DIW supply unit 70 that supplies DIW to the peripheral portion of the wafer W held by the holding unit 31 is constituted by these processing liquid nozzle 71, the processing liquid supply pipe 72, the processing liquid supply source 73, and the processing liquid valve 74.

As illustrated in FIG. 3, the DIW nozzle 71 is connected to a DIW nozzle driving unit 75 via a DIW nozzle arm 76. The DIW nozzle driving unit 75 moves the DIW nozzle 71 between a rinse position P3 where DIW is supplied to the peripheral portion of the wafer W and a retreat position Q2 that is retreated from the wafer W. The DIW nozzle 71 moves in the radial direction of the wafer W between the rinse position P3 and the retreat position Q2. The rinse position P3 is set at such a position where DIW may be supplied so as to wash away the hydrofluoric acid remaining on the upper surface of the wafer W. More specifically, the rinse position P3 may be positioned such that the supply position of DIW to the wafer W is positioned closer to the center O side of the wafer W than the supply position of hydrofluoric acid to the wafer W by the processing liquid nozzle 61. The retreat position Q2 is set at such a position where the DIW ejected from the DIW nozzle 71 does not reach the upper surface of the wafer W.

Control of each component of the substrate processing apparatus 30 is performed by the controller 18 of the control device 4 described above. Specifically, the controller 18 is connected with, for example, the holding unit 31, the rotation driving unit 33, the processing liquid supply unit 60 (particularly, the processing liquid valve 64), and the DIW supply unit 70. Further, the controller 18 is connected with the processing liquid nozzle driving unit 65, the DIW nozzle driving unit 75, and the exhaust unit 48 (particularly, the exhaust driving unit 50 and the flow rate adjusting valve 51). The controller 18 is configured to control each component by sending a control signal to each component connected to the controller 18. The specific contents of control of each component by the controller 18 will be described later.

Next, an operation (wafer W processing method) of the substrate processing apparatus 30 as described above will be described with reference to FIGS. 7 to 16. The operation of the substrate processing apparatus 30 as will be described below is performed by controlling each component of the substrate processing apparatus 30 by the controller 18 according to program (recipe) stored in a storage medium. Here, FIGS. 7 to 16 illustrate views seen in a direction orthogonal to the radial direction of the wafer W.

### Holding Step

First, the wafer W is held horizontally. More specifically, the wafer W is transferred from the outside of the substrate processing apparatus 30 into the chamber 39 via the side opening 52 of the chamber by the substrate transfer device 17 illustrated in FIG. 1. Then, the wafer W is placed on the holding unit 31 in the chamber 39 by the substrate transfer device 17. Here, a natural oxide film is formed on the upper surface of the wafer W placed on the holding unit 31.

### Rotation Start Step

Next, as illustrated in FIG. 7, rotation of the wafer W held by the holding unit 31 is started. More specifically, by driving the rotation driving unit 33 (see FIG. 2), the rotation shaft 32 is rotated about an axis extending in the vertical direction. As a result, the wafer W held by the holding unit 31 is rotated in the horizontal plane. At this time, the rotation driving force of the motor 35 is applied to the rotation shaft 32 via the pulley 36, the driving belt 37, and the pulley 34, so that the rotation shaft 32 is rotated. Here, a rotational speed of the wafer W is set to a first rotational speed R1 (e.g., several tens to several hundreds rpm).

Further, in the rotation start step, the exhaust driving unit 50 is driven, so that the clean air in the cup space S3 is attracted and exhausted. At this time, the flow rate adjusting valve 51 sets an exhaust amount of the clean air discharged from the inner space S1 of the top ring 42 to a first exhaust amount E1.

### Processing Liquid Supply Step

Next, hydrofluoric acid is supplied to the peripheral portion of the wafer W. That is, hydrofluoric acid is supplied from the processing liquid nozzle 61 to a natural oxide film formed at the peripheral portion of the rotating wafer W, so that the natural oxide film is removed.

### Ejection Start Step

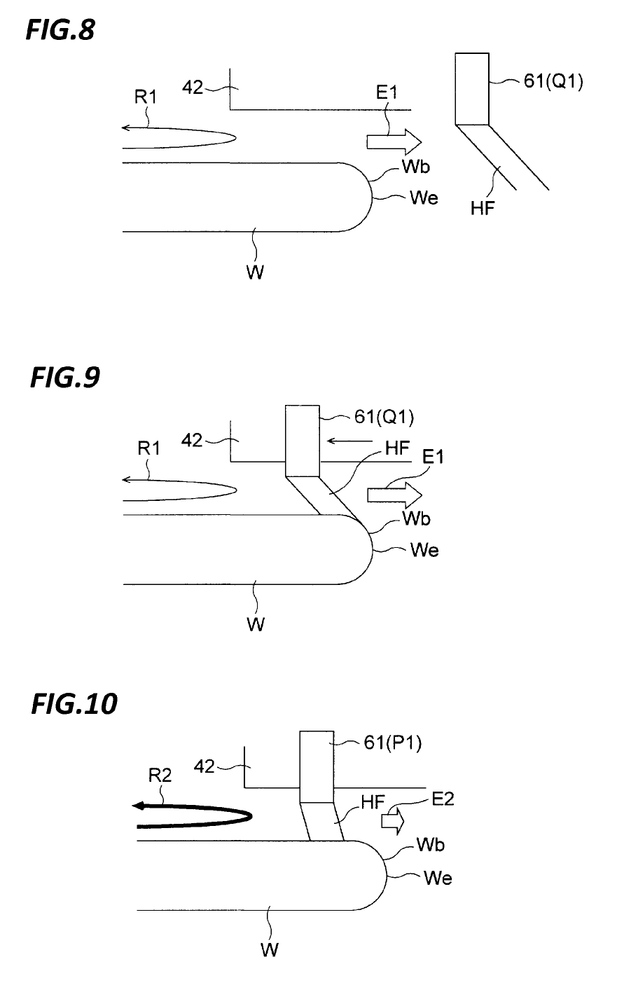

In the processing liquid supply step, first, the processing liquid valve 64 (see FIG. 2) is opened, and as illustrated in FIG. 8, hydrofluoric acid is ejected from the processing liquid nozzle 61 positioned at the retreat position Q1. Hydrofluoric acid is ejected for a predetermined time while the processing liquid nozzle 61 is maintained at the retreat position Q1. Therefore, even in a case where an ejection amount of hydrofluoric acid is small, it is possible to stabilize the ejection amount of hydrofluoric acid. For example, hydrofluoric acid is ejected continuously at an ejecting rate of 15 ml/min for 3 seconds. The ejection amount of hydrofluoric acid is maintained constant until the ejecting stop step described later.

### First Moving Step

Subsequently, as illustrated in FIG. 9, the processing liquid nozzle 61 is moved from the retreat position Q1 to the first processing position P1 while rotating the wafer W at the first rotational speed R1 and ejecting hydrofluoric acid from the processing liquid nozzle 61.

More specifically, the processing liquid nozzle driving unit 65 (see FIG. 3) is driven, so that the processing liquid nozzle 61 is moved from the retreat position Q1 to the first processing position P1. For example, the processing liquid nozzle 61 is moved from the retreat position Q1 to the first processing position P1 in 0.5 seconds. During this time, hydrofluoric acid is continuously ejected from the processing liquid nozzle 61, and the processing liquid nozzle 61 reaches the first processing position P1, so that the supply of hydrofluoric acid to the peripheral portion of the wafer W is started.

In the first moving step, the exhaust amount of the clean air discharged from the inner space S1 is maintained at the first exhaust amount E1 which is larger than a second exhaust amount E2 (to be described later). Therefore, the hydrofluoric acid ejected from the processing liquid nozzle 61 is pulled by the exhaust gas, and the hydrofluoric acid is ejected from the processing liquid nozzle 61 in the direction of the arrow indicated by the broken line in FIGS. 4 to 6.

More specifically, as indicated by the broken line arrow in FIG. 4, when viewed in a direction orthogonal to the radial direction of the wafer W, the ejecting direction of hydrofluoric acid is inclined outward in the radial direction of the wafer W from the ejecting direction indicated by the solid line arrow. Further, as indicated by a broken line arrow in FIG. 5, when viewed in the radial direction of the wafer W, the ejecting direction of hydrofluoric acid is inclined toward the downstream side of the rotation direction of the wafer W from the vertically downward side, but is less inclined than the ejecting direction indicated by the solid line arrow. As a result, when viewed from above the wafer W, as indicated by the broken line arrow in FIG. 6, the ejecting direction of hydrofluoric acid from the processing liquid nozzle 61 is represented by the angle θ2 illustrated in FIG. 6. In this case, it is possible to suppress the hydrofluoric acid that has collided with the bevel portion Wb of the wafer W from being scattered toward the inner peripheral side. In this manner, the ejecting direction of the hydrofluoric acid ejected from the processing liquid nozzle 61 when the exhaust is performed with the first exhaust amount E1 becomes a direction in which the angle formed by the tangent to the wafer W is substantially vertical. That is, the hydrofluoric acid is ejected in such a direction which is directed outward in the radial direction of the wafer W from the downstream side of the rotation direction of the wafer W. Here, the angle θ2 is defined in the same manner as the above-described angle θ1, and defined as an angle formed by an extension line L2 of the broken line arrow indicating the ejecting direction of hydrofluoric acid from the processing liquid nozzle 61 and a tangent line T2 of the wafer W at an intersection of the extension line L2 and the outer edge We of the wafer W.

### Rotational speed Increasing Step

Next, as illustrated in FIG. 10, the rotational speed of the wafer W is increased from the first rotational speed R1 to a second rotational speed R2 (e.g., several tens to 3,000 rpm) that is higher than the first rotational speed R1 while maintaining the processing liquid nozzle 61 at the first processing position P1.

In the rotational speed increasing step, the exhaust amount of the clean air discharged from the inner space S1 is decreased from the first exhaust amount E1 to the second exhaust amount E2 which is smaller than the first exhaust amount E1. Therefore, the hydrofluoric acid is ejected from the processing liquid nozzle 61 in the direction of the arrow indicated by the solid line in FIGS. 4 to 6. In this manner, the ejecting direction of the hydrofluoric acid ejected from the processing liquid nozzle 61 when exhausted at the second exhaust amount E2 becomes such a direction that is directed to the downstream side of the rotation direction of the wafer W than the outer side of the radial direction of the wafer W as indicated by the solid line arrow in FIG. 6. Therefore, as illustrated in FIG. 10, when viewed in a direction orthogonal to the radial direction of the wafer W, a reaching point of the hydrofluoric acid ejected from the processing liquid nozzle 61 on the upper surface of the wafer W is shifted to the center O side of the wafer W.

### Second Moving Step

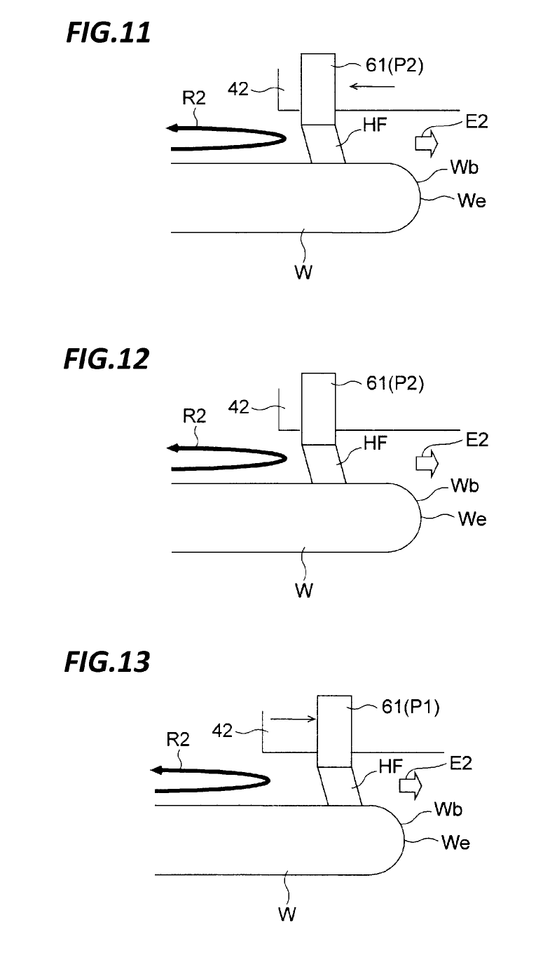

Next, as illustrated in FIG. 11, the processing liquid nozzle 61 is moved from the first processing position P1 to the second processing position P2 while rotating the wafer W at the second rotational speed R2 and ejecting hydrofluoric acid from the processing liquid nozzle 61.

More specifically, the processing liquid nozzle driving unit 65 is driven, so that the processing liquid nozzle 61 is moved from the first processing position P1 to the second processing position P2. For example, the processing liquid nozzle 61 is moved from the first processing position P1 to the second processing position P2 in 0.5 seconds. During this time, the hydrofluoric acid is continuously ejected from the processing liquid nozzle 61.

In the second moving step, the exhaust amount of the clean air discharged from the inner space S1 is maintained at the second exhaust amount E2 which is smaller than the first exhaust amount E1. Therefore, the hydrofluoric acid is ejected from the processing liquid nozzle 61 in the direction indicated by the solid line arrow in FIGS. 4 to 6.

### Natural Oxide Film Removing Step

Next, as illustrated in FIG. 12, the processing liquid nozzle 61 is maintained at the second processing position P2 for a predetermined time. Hydrofluoric acid is continuously supplied from the processing liquid nozzle 61 to the natural oxide film formed at the peripheral portion of the wafer W which is rotating. A supply position of the hydrofluoric acid from the processing liquid nozzle 61 positioned at the second processing position P2 is set to such a position where a region corresponding to the etching width of the natural oxide film on the wafer W may be removed. Therefore, the above-described region in the natural oxide film is removed by etching with hydrofluoric acid, so that the upper surface of the peripheral portion of the wafer W is exposed. For example, hydrofluoric acid is continuously ejected from the processing liquid nozzle 61 positioned at the second processing position P2 for 60 seconds. The hydrofluoric acid ejected to the peripheral portion of the wafer W is subjected to a centrifugal force due to the rotation of the wafer W, flows from the peripheral portion of the wafer W to the outer peripheral side, and is discharged from the bevel portion Wb of the wafer W. In the natural oxide film removing step, in order to improve the removal accuracy of the natural oxide film, the rotational speed of the wafer W may be set to be as high as the second rotational speed R2. Therefore, the centrifugal force may be applied to the hydrofluoric acid supplied to the wafer W, and it is possible to suppress the hydrofluoric acid on the upper surface of the wafer W from advancing to the inner peripheral side. In this case, the accuracy of the etching width of the natural oxide film may be improved.

### Third Moving Step

Next, as illustrated in FIG. 13, the processing liquid nozzle 61 is moved from the second processing position P2 to the first processing position P1 while rotating the wafer W at the second rotational speed R2 and ejecting hydrofluoric acid from the processing liquid nozzle 61.

More specifically, the processing liquid nozzle driving unit 65 is driven, so that the processing liquid nozzle 61 is moved from the second processing position P2 to the first processing position P1. For example, the processing liquid nozzle 61 is moved from the second processing position P2 to the first processing position P1 in 0.5 seconds. During this time, the hydrofluoric acid is continuously ejected from the processing liquid nozzle 61.

### Rotational Speed Decreasing Step

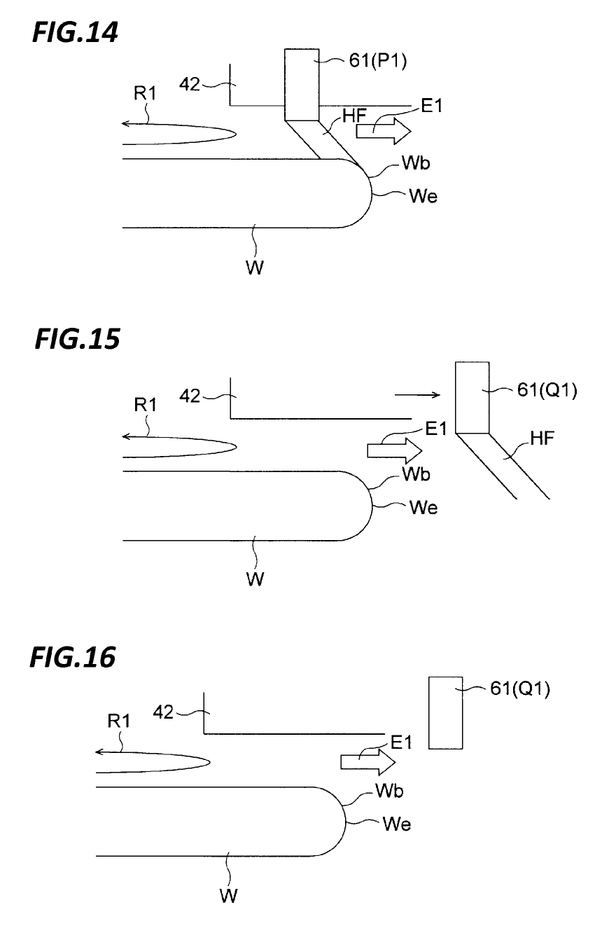

Next, as illustrated in FIG. 14, the rotational speed of the wafer W is decreased from the second rotational speed R2 to the first rotational speed R1 while maintaining the processing liquid nozzle 61 at the first step position P1.

In the rotational speed decreasing step, the exhaust amount of the clean air discharged from the inner space S1 is increased from the second exhaust amount E2 to the first exhaust amount E1. Therefore, the hydrofluoric acid is ejected from the processing liquid nozzle 61 in the direction indicated by the broken line arrow in FIGS. 4 to 6. In this manner, the ejecting direction of the hydrofluoric acid ejected from the processing liquid nozzle 61 when exhausted at the first exhaust amount E1 becomes such a direction that is directed outward in the radial direction of the wafer W from the downstream side of the rotation direction of the wafer W. Therefore, as illustrated in FIG. 14, when viewed in a direction orthogonal to the radial direction of the wafer W, a reaching point of the hydrofluoric acid ejected from the processing liquid nozzle 61 on the upper surface of the wafer W is shifted to the outer edge We side of the wafer W.

### Fourth Moving Step

Next, as illustrated in FIG. 15, the processing liquid nozzle 61 is moved from the first processing position P1 to the second processing position P2 while rotating the wafer W at the first rotational speed R1 and ejecting hydrofluoric acid from the processing liquid nozzle 61.

More specifically, the processing liquid nozzle driving unit 65 is driven, so that the processing liquid nozzle 61 is moved from the first processing position P1 to the retreat position Q1. For example, the processing liquid nozzle 61 is moved from the first processing position P1 to the retreat position Q1 in 0.5 seconds. During this time, hydrofluoric acid is continuously ejected from the processing liquid nozzle 61, and the processing liquid nozzle 61 reaches the retreat position Q1, so that the supply of hydrofluoric acid to the peripheral portion of the wafer W is ended.

### Ejection Stop Step

Thereafter, the processing liquid valve 64 is closed, and the ejection of the hydrofluoric acid from the processing liquid nozzle 61 positioned at the retreat position Q1 is stopped. In this way, the processing liquid supply step is completed. The stop of the ejection of the hydrofluoric acid from the processing liquid nozzle 61 is not limited to being performed after the processing liquid nozzle 61 reaches the retreat position Q1. For example, in the above-described rotational speed decreasing step, the stop of the ejection of the hydrofluoric acid may be performed after the rotational speed of the wafer W positioned at the first processing position P1 is decreased to the first rotational speed R1. Further, the procedure of retreating the processing liquid nozzle 61 to the retreat position Q1 after the natural oxide film removing step is not limited to the above-described procedure, but is arbitrary.

### DIW Supply Step

After completion of the above-described processing liquid supply step, DIW as a rinse liquid is supplied to the peripheral portion of the wafer W. In the DIW supply step, the rotational speed of wafer W is, for example, 600 rpm. Further, the exhaust amount of the clean air discharged from the exhaust passage 49 is decreased to the second exhaust amount E2 which is smaller than the first exhaust amount E1.

More specifically, first, the DIW valve 74 is opened, and the DIW is ejected from the DIW nozzle 71. Continuously, the DIW nozzle driving unit 75 is driven, so that the DIW nozzle 71 is moved from the retreat position Q2 to the rinse position P3. Next, the DIW nozzle 71 is maintained at the rinse position P3 for a predetermined time. The rinse position P3 of the DIW nozzle 71 is set to such a position where the supply position of DIW to the wafer W is closer to the center O of the wafer W than the supply position of hydrofluoric acid to the wafer W. Therefore, the wafer W is subjected to the rinse step, so that the hydrofluoric acid remaining on the upper surface of the wafer W may be washed away. The DIW ejected to the peripheral portion of the wafer W is subjected to a centrifugal force due to the rotation of the wafer W, flows from the peripheral portion of the wafer W to the outer peripheral side, and is discharged from the bevel portion Wb of the wafer W. Subsequently, the DIW nozzle driving unit 75 is driven and the DIW nozzle 71 is moved from the rinse position P3 to the retreat position Q2. Thereafter, the DIW valve 74 is closed and the ejecting of the DIW from the DIW nozzle 71 positioned at the retreat position Q2 is stopped. Therefore, the DIW supply step is completed.

### Dry Step

After the completion of the above-described DIW supply step, the rotational speed of the wafer W is increased, and the dry step of the wafer W is performed. For example, the rotational speed of the wafer W is set to 2500 rpm. Therefore, the DIW remaining on the upper surface of the wafer W is subjected to a centrifugal force due to the rotation of the wafer W, flows from the peripheral portion of the wafer W to the outer peripheral side, and is discharged from the bevel portion Wb of the wafer W. As a result, the DIW is removed from the upper surface of the wafer W, and the upper surface of the wafer W is dried.

As described above, according to an embodiment of the present disclosure, first, the processing liquid nozzle 61 is moved from the retreat position Q1 to the first processing position P1 while rotating the wafer W at the first rotational speed R1 and ejecting hydrofluoric acid from the processing liquid nozzle 61. Thereafter, the processing liquid nozzle 61 is moved from the first processing position P1 to the second processing position P2 while rotating the wafer W at the second rotational speed R2 and ejecting hydrofluoric acid from the processing liquid nozzle 61. Therefore, a rotational speed of the wafer W while moving the processing liquid nozzle 61 from the retreat position Q1 to the first processing position P1 may be lower than a rotational speed of the wafer while moving the processing liquid nozzle 61 from the first processing position P1 to the second processing position P2. When the processing liquid nozzle 61 passes through the position where the hydrofluoric acid ejected from the processing liquid nozzle 61 collides with the bevel portion Wb of the wafer W, the rotational speed of the wafer W may be lowered. Therefore, it is possible to suppress the hydrofluoric acid that has collided with the bevel portion Wb of the wafer W from being scattered, and it is possible to suppress the hydrofluoric acid from being scattered toward the surface of the natural oxide film remaining after etching. As a result, it is possible to suppress hydrofluoric acid from becoming a particle source and remaining on the upper surface of the wafer W. In addition, it is possible to suppress generation of particles on the upper surface of the wafer W.

In particular, in a case where the upper surface of the wafer W is formed of a hydrophobic surface, or in a case where a hydrophobic surface and a hydrophilic surface are mixed, the hydrofluoric acid colliding with the bevel portion Wb of the wafer is likely to be scattered. However, since the rotational speed of the wafer is low as described above, scattering of the hydrofluoric acid toward the inner peripheral side may be suppressed. Further, by suppressing the scattering of the wafer W, it is possible to suppress the scattered hydrofluoric acid from adhering to parts (e.g., the top ring 42 or the processing liquid nozzle 61) that are present around the bevel portion Wb of the wafer W. In addition, in the present embodiment, when the processing liquid nozzle 61 passes through the position where the hydrofluoric acid collides with the bevel portion Wb of the wafer W, since the rotational speed of the wafer W becomes low, a liquid film of the hydrofluoric acid may be formed on the curved surface of the bevel portion Wb of the wafer W and the natural oxide film formed on the surface of the bevel portion may be effectively etched and removed.

In addition, according to the present embodiment, after moving the processing liquid nozzle 61 from the retreat position Q1 to the first processing position P1, the rotational speed of the wafer W is increased from the first rotational speed R1 to the second rotational speed R2 while maintaining the processing liquid nozzle 61 at the first processing position P1. Therefore, when the processing liquid nozzle 61 is moved from the first processing position P1 to the second processing position P2, the rotational speed of the wafer W may be increased to the second rotational speed R2. As a result, the accuracy of the etching width of the natural oxide film may be improved.

Further, according to the present embodiment, when the processing liquid nozzle 61 is moved from the retreat position Q1 to the first processing position P1, the clean air in the inner space Si of the top ring 42 is discharged at the first exhaust amount E1 through the peripheral space S2 interposed between the top ring 42 and the peripheral portion of the wafer W. When the processing liquid nozzle 61 is moved from the first position P1 to the second processing position P2, the clean air in the inner space 51 is discharged at the second exhaust amount E2 through the peripheral space S2. Therefore, the exhaust amount of the clean air in the inner space S1 when the processing liquid nozzle 61 is moved from the retreat position Q1 to the first processing position P1 may be larger than the exhaust amount of the clean air in the inner space S1 when the processing liquid nozzle 61 is moved from the first processing position P1 to the second processing position P2, and when the processing liquid nozzle 61 passes through the position where the hydrofluoric acid ejected from the processing liquid nozzle 61 collides with the bevel portion Wb of the wafer W, the exhaust amount of the clean air in the inner space S1 may be increased. Therefore, it is possible to suppress the hydrofluoric acid that has collided with the bevel portion Wb of the wafer W from being scattered so that the hydrofluoric acid may be discharged from the bevel portion Wb of the wafer W to the outer peripheral side, and it is possible to further suppress the hydrofluoric acid from being scattered toward the surface of the natural oxide film remaining after etching.

Further, according to the present embodiment, when the rotational speed of the wafer W is increased from the first rotational speed R1 to the second rotational speed R2, the exhaust amount of the clean air in the inner space S1 of the top ring 42 is decreased from the first exhaust amount E1 to the second exhaust amount E2. Therefore, when the processing liquid nozzle 61 is moved from the first processing position P1 to the second processing position P2, the ejecting direction of the hydrofluoric acid from the processing liquid nozzle 61 may be directed to the downstream side of the rotation direction of the wafer W. As a result, the accuracy of the etching of the natural oxide film may be improved.

Further, according to the present embodiment, while the processing liquid nozzle 61 is moved from the retreat position Q1 to the second processing position P2 via the first processing position P1, the ejection amount of the hydrofluoric acid ejected from the processing liquid nozzle 61 is maintained constantly. Therefore, even in a case where the ejection amount of the hydrofluoric acid is reduced in order to remove the natural oxide film in the limited region, i.e., the peripheral portion of the wafer W, the ejection amount when the processing liquid nozzle 61 reaches the second processing position P2 may be stabilized. As a result, the accuracy of the etching width of the natural oxide film may be improved.

Further, according to the present embodiment, the processing liquid nozzle 61 is moved from the second processing position P2 to the first processing position P1 while rotating the wafer W at the second rotational speed R2 and ejecting hydrofluoric acid from the processing liquid nozzle 61. Thereafter, the processing liquid nozzle 61 is moved from the first processing position P1 to the retreat position Q1 while rotating the wafer W at the first rotational speed R1 and ejecting hydrofluoric acid from the processing liquid nozzle 61. Therefore, a rotational speed of the wafer W while moving the processing liquid nozzle 61 from the first processing position P1 to the retreat position Q1 may be lower than a rotational speed of the wafer while moving the processing liquid nozzle 61 from the second processing position P2 to the first processing position P1. When the processing liquid nozzle 61 passes through the position where the hydrofluoric acid ejected from the processing liquid nozzle 61 collides with the bevel portion Wb of the wafer W, the rotational speed of the wafer W may be lowered. Therefore, it is possible to suppress the hydrofluoric acid that has collided with the bevel portion Wb of the wafer W from being scattered, and it is possible to suppress the hydrofluoric acid from being scattered toward the surface of the natural oxide film remaining after etching.

In the above-described embodiment, the example in which the processing liquid nozzle 61 is ejecting hydrofluoric acid while moving from the retreat position Q1 to the first processing position P1 has been described. However, the present disclosure is not limited thereto, and the processing liquid nozzle 61 is configured to be able to eject a plurality of kinds of processing liquids different from each other. The processing liquid ejected from the processing liquid nozzle 61 in the first moving step and the processing liquid ejected from the processing liquid nozzle 61 in the second moving step may be different from each other. For example, the processing liquid nozzle 61 may be configured to eject DIW as an example of a processing liquid instead of hydrofluoric acid while moving from the retreat position Q1 to the first processing position P1 (the first moving step). In this case, the DIW supply pipe 72 illustrated in FIG. 3 is connected to the processing liquid nozzle 61, and the processing liquid nozzle 61 may be configured to be able to selectively eject hydrofluoric acid and DIW.

More specifically, in the first moving step, DIW is supplied from the DIW supply source 73 to the processing liquid nozzle 61 and ejected from the processing liquid nozzle 61. In the rotational speed increasing step, the processing liquid supplied to the processing liquid nozzle 61 is switched from the DIW to hydrofluoric acid. At this time, the processing liquid nozzle 61 may be maintained at the first processing position P1 until the ejection amount of hydrofluoric acid ejected from the processing liquid nozzle 61 is stabilized. Thereafter, in the second moving step, hydrofluoric acid is ejected from the processing liquid nozzle 61. Also in this case, the rotational speed of the wafer W while the processing liquid nozzle 61 is moved from the retreat position Q1 to the first processing position P1 is decreased. Thus, scattering of the DIW colliding with the bevel portion Wb of the wafer W may be suppressed. Further, in this case, the hydrofluoric acid ejected from the processing liquid nozzle 61 may be supplied to the DIW liquid film formed on the upper surface of the wafer W instead of the dried upper surface of the wafer W. Therefore, it is possible to suppress the hydrofluoric acid supplied to the upper surface of the wafer W from bouncing off from the upper surface and scattering on the upper surface, and suppress formation of a particle source.

Further, in the case where the processing liquid nozzle 61 is configured to be able to selectively eject hydrofluoric acid and DIW, after the natural oxide film removing step, without moving the processing liquid nozzle 61 to the retreat position Q1, the upper surface of the wafer W may be subjected to the rinse step. That is, by switching the processing liquid ejected from the processing liquid nozzle 61 from hydrofluoric acid to DIW while maintaining the processing liquid nozzle at the second processing position P2, the upper surface of the wafer W may be subjected to the rinse step. Therefore, the step may be simplified.

Further, even when the processing liquid nozzle 61 is not configured to selectively eject hydrofluoric acid and DIW, DIW may be first ejected from the DIW nozzle 71 to the peripheral portion of the surface of the wafer W in the ejection start step in the processing liquid supply step. Thereafter, hydrofluoric acid may be ejected from the processing liquid nozzle 61 and the processing liquid nozzle 61 may be moved from the retreat position Q1 to the first processing position Pl. While moving the processing liquid nozzle 61, DIW is continuously ejected from the DIW nozzle 71. In this case, the hydrofluoric acid ejected from the processing liquid nozzle 61 may be supplied to the DIW liquid film formed on the upper surface of the wafer W instead of the dried upper surface of the wafer W. Therefore, it is possible to suppress the hydrofluoric acid supplied to the upper surface of the wafer W from bouncing off from the upper surface and scattering on the upper surface, and suppress formation of a particle source. The supply position of DIW may be arranged in the vicinity of the upstream side of the rotation direction of the wafer from the supply position of hydrofluoric acid when viewed in a plan view.

Instead of DIW, for example, ozone water, nitric acid, or sulfuric acid may also be used. As a substitute for these DIWs, any liquid may be used as long as it has oxidizing power and does not have an etching action on a silicon-based wafer W.

Further, in the above-described embodiment, the example in which the exhaust unit 48 has the flow rate adjusting valve 51 that adjust the exhaust amount of the clean air discharged from the inner space S1 has been described. However, the configuration is not limited thereto as long as the exhaust amount is adjustable. For example, a plurality of exhaust passages that have flow rates different from each other may be formed, and these exhaust passages may be configured to be selectively connected to the exhaust ports 47. Also in this case, the exhaust amount of the clean air discharged from the inner space S1 may be switched.

Further, in the above-described embodiment, the example in which the substrate processing apparatus 30 is an apparatus configured to remove the natural oxide film formed at the peripheral portion of the wafer W by etching has been described. However, the present disclosure is not limited thereto, and the substrate processing apparatus 30 may be an apparatus configured to remove other types of films formed at the peripheral portion of the wafer W by etching. For example, the substrate processing apparatus 30 may be an apparatus configured to remove a resist film formed at the upper surface of the wafer W. In this case, a resist removing liquid (resist remover) that removes a resist film is used as a processing liquid.

Further, in the above-described embodiment, hydrofluoric acid has been described as an example of a processing liquid for removing the natural oxide film formed on the upper surface of the wafer by etching. However, the present disclosure is not limited thereto, and other chemical liquids (e.g., dilute hydrofluoric acid (DHF) which is an aqueous solution containing hydrofluoric acid) may be used as long as the film formed on the peripheral portion of the wafer W can be removed.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a holding unit configured to hold a substrate in a horizontal direction;
a rotation driving unit configured to rotate the holding unit;
a processing liquid supply unit including a processing liquid nozzle configured to eject a processing liquid;
a processing liquid nozzle driving unit configured to move the processing liquid nozzle among a first processing position where the processing liquid is supplied to the substrate, a second processing position that is positioned closer to a center side of the substrate than the first processing position where the processing liquid is supplied to the substrate, and a retreat position that is retreated from the substrate; and
a controller configured to control an overall operation of the substrate processing apparatus,
wherein the controller controls the rotation driving unit, the processing liquid supply unit, and the processing liquid nozzle driving unit so as to perform a first moving of moving the processing liquid nozzle from the retreat position to the first processing position while rotating the substrate at a first rotational speed and ejecting the processing liquid from the processing liquid nozzle, and, after performing the first moving, a second moving of moving the processing liquid nozzle from the first processing position to the second processing position while rotating the substrate at a second rotational speed that is higher than the first rotational speed and ejecting the processing liquid from the processing liquid nozzle.

2. The substrate processing apparatus of claim 1, wherein the controller controls the rotation driving unit and the processing liquid nozzle driving unit so as to perform a rotational speed increasing of increasing a rotational speed of the substrate from the first rotational speed to the second rotational speed while maintaining the processing liquid nozzle at the first processing position between the first moving and the second moving.

3. The substrate processing apparatus of claim 2, further comprising:
a ring-shaped cover member that defines an inner space formed above the substrate held by the holding unit and covers a peripheral portion of the substrate via a peripheral space communicating with the inner space; and
an exhaust unit that discharge a gas in the inner space of the cover member through the peripheral space,
wherein the exhaust unit includes an exhaust amount adjusting unit that adjust an exhaust amount of the gas discharged from the inner space, and
the controller controls the exhaust unit so as to discharge the gas in the inner space at a first exhaust amount in the first moving and discharge the gas in the inner space at a second exhaust amount that is smaller than the first exhaust amount in the second moving.

4. The substrate processing apparatus of claim 3, wherein the controller controls the exhaust unit so as to decrease the exhaust amount of the gas in the inner space from the first exhaust amount to the second exhaust amount in the rotational speed increasing.

5. The substrate processing apparatus of claim 1, further comprising:
a ring-shaped cover member that defines an inner space formed above the substrate held by the holding unit and covers a peripheral portion of the substrate via a peripheral space communicating with the inner space; and
an exhaust unit that discharge a gas in the inner space of the cover member through the peripheral space,
wherein the exhaust unit includes an exhaust amount adjusting unit that adjust an exhaust amount of the gas discharged from the inner space, and
the controller controls the exhaust unit so as to discharge the gas in the inner space at a first exhaust amount in the first moving and discharge the gas in the inner space at a second exhaust amount that is smaller than the first exhaust amount in the second moving.

6. The substrate processing apparatus of claim 1, wherein the processing liquid nozzle is configured to eject a plurality of types of processing liquids different from each other, and
the processing liquid ejected from the processing liquid nozzle in the first moving and the processing liquid ejected from the processing liquid nozzle in the second moving are different from each other.

7. A substrate processing method comprising:
holding a substrate on a holding unit in a horizontal direction;
performing a first moving of moving a processing liquid nozzle from a retreat position that is retreated from the substrate to a first processing position where a processing liquid is supplied to the substrate while rotating the substrate at a first rotational speed and ejecting the processing liquid from the processing liquid nozzle; and
after performing the first moving, performing a second moving of moving the processing liquid nozzle from the first processing position to a second processing position that is positioned closer to a center side of the substrate than the first processing position where the processing liquid is supplied to the substrate while rotating the substrate at a second rotational speed that is higher than the first rotational speed and ejecting the processing liquid from the processing liquid nozzle.

8. The substrate processing method of claim 7, further comprising:
performing a rotational speed increasing of increasing the rotational speed of the substrate from the first rotational speed to the second rotational speed while maintaining the processing liquid nozzle at the first processing position between the first moving and the second moving.

9. The substrate processing method of claim 8, wherein a ring-shaped cover member is disposed above the substrate,
the cover member defines an inner space formed above the substrate,
a peripheral portion of the substrate is covered with the cover member via a peripheral space communicating with the inner space, and
a gas in the inner space is discharged at a first exhaust amount in the performing of the first moving and the gas in the inner space is discharged through the peripheral space at a second exhaust amount that is smaller than the first exhaust amount in the performing of the second moving.

10. The substrate processing method of claim 9, wherein an exhaust amount of the gas in the peripheral space is decreased from the first exhaust amount to the second exhaust amount in the performing of the rotational speed increasing.

11. The substrate processing method of claim 7, wherein a ring-shaped cover member is disposed above the substrate,
the cover member defines an inner space formed above the substrate,
a peripheral portion of the substrate is covered with the cover member via a peripheral space communicating with the inner space, and
a gas in the inner space is discharged at a first exhaust amount in the performing of the first moving and the gas in the inner space is discharged through the peripheral space at a second exhaust amount that is smaller than the first exhaust amount in the performing of the second moving.

12. The substrate processing method of claim 7, wherein the processing liquid nozzle is configured to eject a plurality of types of processing liquids different from each other, and
the processing liquid ejected from the processing liquid nozzle in the performing of the first moving and the processing liquid ejected from the processing liquid nozzle in the performing of the second moving are different from each other.

13. A non-transitory computer-readable storage medium that stores a program that causes a computer to execute the substrate processing method of claim 7.
